(19) United States
(12) Patent Application Publication
(10) Pub. No.: US 2011/0041891 A1
(43) Pub. Date: Feb. 24, 2011

(54) PHOTOVOLTAIC MODULES AND PRODUCTION PROCESS

(75) Inventors: Francois Rummens, Bruxelles (BE); Jochen Bossuyt, Kerkhove (BE)

Correspondence Address: Fanelli Strain & Haag PLLC, 1455 Pennsylvania Ave., N.W., suite 400, Washington, DC, 20004, US

(73) Assignee: RENOLIT BELGIUM N.V.

(21) Appl. No.: 12/865,619

(22) PCT Filed: Feb. 2, 2009
(86) PCT No.: PCT/EP09/00665

§ 371 Date: Nov. 1, 2010

(30) Foreign Application Priority Data
Feb. 2, 2008 (EP) 08001990.4
Feb. 2, 2008 (EP) 08001991.2

(51) Int. Cl. H01L 31/042

(52) U.S. Cl. 136/244

(57) ABSTRACT

The flexible photovoltaic module (1) with good external fire performance comprises photovoltaic cells (1c) on plastic substrate and plastic sheet or adhesive layer (1d) under cell based on polyolefin, and/or copolymer of ethylene or propylene with vinyl acetate or (meth)acrylates or neutralized acrylic acids (ionomers). The plastic sheet or adhesive layer contains at least 50 (preferably 100) g/m² halogenated (preferably brominated) flame retardant. The layers above plastic sheet allow release of flame poisoning substances coming from plastic sheet when fire is set to module.

The present invention relates to compositions and cost effective processes to produce integrated photovoltaic modules for consumer and roofing applications.

To obtain cost effective Photovoltaic applications, it is required to integrate the modules within the applications and/or speed-up production steps and/or use cost effective processes and materials.

For roofing applications, photovoltaic integrated roofing membranes already exist and are described in DE 29824045 U1 and WO2004066324 A2: To obtain a roof with photovoltaic modules attached onto it, one uses, as waterproofing membrane, a waterproofing membrane with factory laminated flexible light weight photovoltaic (PV) modules on top of it. Such PV integrated waterproofing membranes are produced by companies like SIT (Solar Integrated) in the USA or by Alwitra in Germany. They consist of several elongated flexible modules supplied e.g. by United Solar Ovonic (Uni-Solar modules PVL 136), containing cells on metal foils, glued in parallel to the polymeric waterproofing membrane. Because the cells are built on metal sheet, they form a fire barrier between external fire and the waterproofing membrane. Such photovoltaic waterproofing membranes meet therefore the fire requirements for roofing application.

EP 0 769 818 A2 and EP 1 458 035 A2 describe a typical composition of elongated flexible modules containing cells on metal foils. Commercially available laminates (e.g. Uni-Solar PVL 136) have further been analyzed by optical and electronic microscopy and IR analysis and are of the same composition as described by the patent applications EP 0 769 818 A2 and EP 1 458 035 A2. The following layers are detected:

50 μm ETFE

maximum 800 μm glassfleece or beads containing EVA (High Vinyl Acetate content, peroxide crosslinked, with adhesion promoters). 800 μm is the maximum thickness allowing obtaining superior flammability.

120 μm stainless steel foil supporting the active layers (triple junction)

150 μm EVA (high Vinyl Acetate content, peroxide crosslinked, with adhesion promoters)

100 μm EVA low Vinyl Acetate content

a few micrometers of PUR glue

50 μm PET dielectric laminate film

a few micrometers of PUR glue

100 μm EVA low Vinyl Acetate content.

The PET film is required for electrical safety. The “EVA low Vinyl Acetate” layers are glued to the PET film with PUR adhesives. Obtaining a good adhesion between EVA and PET is not an easy task. The PET film reaches further the edges of the module. After 4 weeks immersion of such module into water at 80° C., one observes indeed delamination at the PET interface, with potential safety issue as result.

Although the stainless steel foil is an obvious fire barrier, according to EP 0 769 818 A2 and EP 1 458 035, the thickness of the plastic film above the stainless steel foil is limited to 800 μm for flammability reason.

In the following text, in the context of transparent adhesive, EVA will refer to EVA with high amount of Vinyl Acetate (>24%) unless indicated otherwise.

These photovoltaic waterproofing membranes suffer from several drawbacks. They are expensive because they are produced in two steps (production of the PV modules in the first step and lamination in a second step). Further, the modules are also expensive: they are based on interconnected (with by-pass diodes) rectangular pieces of cells on metallic substrate, which are expensive to assemble and to encapsulate. Such modules and cells are described in EP 1 458 035 A2 and EP 0 769 818 A2 and in Handbook of Photovoltaic Science and Engineering (Antonio Luque and Steven Hegedus; in particular chapter 12): The cells are built on a typically 120 μm thick stainless steel foil. The foil is cut in rectangles of typically 40 cm*30 cm and connected in serial with metal strips and encapsulated to obtain a PV module. By-pass diodes are required to avoid that the cells become resistive when shadow covers the cells. An insulating film (PET) is also required under the metal foil to reduce the risk of electrical breakdown and electric shocks.

The interconnected rectangular metal pieces (substrate for the PV cells) will expand and contract leading to differential dilatation issues, meaning internal tensions between plastic films and metal pieces. The metal substrate blocks the diffusion of water vapor coming from inside the building, leading to hydrolytic degradation of the encapsulation material of the PV modules and especially of the glues (adhesion PET/PUR/EVA). Combined with the internal tension, this can lead to internal delamination of the PV modules (hydrolysis of PET dielectric laminate, debonding of PET from EVA layers) or delamination from the waterproofing sheet (hydrolysis of PUR glues, etc . . . ).

U.S. Pat. No. 6,729,081 describes a light weight photovoltaic module which is self-adhesive and can be glues on metal sheets like aluminium sheets. Such sheets (e.g. the Kalzip®AluPlusSolar product) are then installed on aluminium corrugated roofs. Several productions steps are required:

Production of the expensive modules

Lamination with a self-adhesive

Lamination on the metal sheet (aluminium sheet)

So there is a need to develop integrated PV solutions with cost effective cells and materials that can be produced into PV membranes in a one step process. This problem is solved by integrated photovoltaic modules consisting of: a substrate, a thermoplastic adhesive layer with acrylic acids and/or maleic anhydrides functionalities, interconnected cells (4) and a superstrate, which are laminated together in a one step process.

This invention allows to achieve the production of cheap integrated photovoltaic modules, like photovoltaic waterproofing membranes or rigid photovoltaic panels in a one step process, based on cost effective preferably plastic PV cells and processes like roll to roll approach, allowing easy use/installation and allowing to meet the requirements for roofing applications like fire requirements, safety and durability.

The photovoltaic cells which are useful for this invention are preferably thin film photovoltaic cells deposited on stainless steel or plastic films.

Cost effective “monolithically interconnected cells on plastic films” (further referred in the text as “Plastic (PV) cell(s)” are preferred for their cost and insulating properties (dielectric) and are today produced by several groups and companies. Such films are described e.g. in WO 98/13882 and in Handbook of Photovoltaic Science and Engineering (Antonio Luque and Steven Hegedus; in particular chapter 12).

Plastic films have poor fire properties compared to stainless steel foils which is one problem to be solved.

The PV Cell(s) for this invention may consist of:

a base plastic film like typically 20 to 250 μm Kapton® or PEN (polyethylene naphthalate) or PET (polyethylene terephthalate) film or a stainless steel film (with an insulation layer for the monolithic integration)

on this film, in a cheap roll to roll process, one makes the deposition or transfer of:

i) a back electrode (aluminium, etc.)
ii) an active PV layer or layers
iii) a transparent front electrode, like a transparent conductive oxide.

Acids, oxygen and water vapor Barrier layers may be added under a) and above c) if required. Useful barriers are SiOx or Al2O3 layers with hybrid polymers (Ormocers®) or layers obtained by Atomic Layer Deposition, etc.

The layers a), b) and c) are interconnected e.g. by lift-up, laser scribing, etching and silk printing of Ag paste continuous processes, . . . . They form strips of interconnected cells of typically 5 to 25 mm width. Such plastic PV cells are cheap compared to the PV cells built on metal foil that are known in the art.

The active layers may be: a-Si cells, tandem cell (a-Si, a-Si or a-Si, microcrystalline silicon, . . . ), triple junction a-Si/a-SiGe/a-SiGe, Organic PhotoVoltaic (OPV), CIGS, etc.

The cells are preferably serial connected in strips of around 5 to 25 mm, like e.g. described in WO 98/13882 (for example by lift-up, laser, etching and silk printing of Ag paste processes, . . . ) or as described in Handbook of Photovoltaic Science and Engineering (see in particular chapter 12).

The cells are theoretically endless but may be interrupted every e.g. 3 to 30 m to allow for cutting the obtained modules after encapsulation.

The substrate film and cells may be treated to improve adhesion to the adhesive layers (tie-layers). Useful techniques are Corona, Flame treatment, Atmospheric plasma activation, Atmospheric or low pressure plasma deposition (aerosol assisted, . . . ) and/or polymerization, (reactive) Sputtering of metals like Aluminium (Al2O3), atomic layer deposition, . . . . The techniques may be combined and used to coat the cells/films with barrier layers.

A very useful technique to improve adhesion with tie-layers of this invention is reactive sputtering of Al2O3. Sputtering is general used to coat the plastic films with the back electrode (aluminium) and to bring the front electrode (a transparent conductive oxide e.g. ITO). During these operations, it is easy to add a nanometric layer of Al2O3 on the back-side of the plastic film and on the top side above the transparent conductive oxide layer (e.g. ITO). In situ Radio Frequence O2 chemical etching of plastic film is usually performed before coating to improve adhesion of the sputtered layer as well known by the man skilled in the art.

More details about light weight flexible photovoltaic cells and modules (and the process of laminating them in e.g. a vacuum laminator) can be found in numerous patents and patent applications like EP 0769 818 A2, WO 2006/089044, WO 98/13882, and in the patents from the following companies:
Konarka (Organic photovoltaic and Graetzel cells and modules).
VHF—Flexcell (a-Si:H cells and modules)
Helianthos/AKZO NOBEL (a-Si:H cells and modules)
Powerfilm (Iowa Thin Film) (a-Si:H cells and modules)
Canon, (a-Si:H cells and modules)
Fugi, (a-Si:H cells and modules)
United Solar Ovonic, (a-Si:H and triple junction cells and modules)

The objects are especially solved by the present invention as exemplified for roofing application by providing a preferably reinforced waterproofing membrane like a TPO waterproofing sheet (PP or PE based) or a metal sheet (like an aluminium sheet) or another adequate substrate preferably in the form of a roll or coil, encapsulating and laminating the preferably Plastic PV cell(s) on the TPO waterproofing membrane or metal sheet or another substrate in a laminating machine, with sealed edges, with the following stack of preferably flexible layers:
a) A transparent front sheet preferably of fluoropolymer film (typically 20 to 200 μm of ETFE, FEP, PVDF/acrylic . . . , containing, if required, stabilizer and possibly long lasting UV absorbers). The film is surface treated to improve its adhesion on layer b).
b) A transparent adhesive layer (e.g. based on EVA, ionomers, silicone, silicone-urea block polymers, tie-layer, tie-layer/transparent TPO/tie-layer, etc.; total thickness 50 to 2000 μm) or layers.
c) The preferably plastic PV cells, which may be coated beforehand with barrier layers and/or be surface treated to improve adhesion to layer b) and d).
d) a tie-layer or a coextruded layer (tie-layer/TPO; tie-layer1/TTO/tie-layer2), preferably opaque and if required flame retarded, to provide acceptable external fire performances to the final product, e.g. a PV TPO waterproofing membrane.
e) Substrate: e.g. metal sheet or a flame retarded TPO waterproofing membrane.

The TPO of the tie-layer/TPO will improve adhesion with the TPO membrane. The tie-layer2 is designed to provide adhesion to the metal sheet (e.g. aluminium).

The obtained PV waterproofing membrane is then installed on the roof as known per se (e.g. flaps without PV elements are used for mechanically attaching the PV waterproofing membrane on the roof and for welding operations). The metal sheet with integrated PV cells is installed e.g. on metal roofs or on plastic profiles with insert, with the help of e.g. screws (the flaps without active cells are used for mechanically attaching the PV metal sheet and may be corrugated or folded).

Layer a, b, c) are referred as “superstrate”. Alternatively, they may be replaced by a glass plate with PV cells (front electrode/active layers/back electrode, typically aluminium).

Suitable lamination machines are vacuum laminators, membrane presses and isobaric double-belt presses (Roll to roll process), which are well known by the man skilled in the art of lamination.

Suitable EVA films are supplied by Etimex under the trade name Vistasolar 486.10 (thickness=460 μm). Useful EVA films formulation are e.g. described in WO 99/27588. A typical lamination temperature for EVA films is 155° C. (15 minutes).

Tie layers are preferably on base of polyolefin copolymers with acrylic acid or grafted with maleic anhydride.

To improve adhesion between the several layers, they may be treated by techniques like Corona (under O2/N2 or under N2 or N2/CO2 or N2/NH3, etc.), Flame treatment, Atmospheric plasma activation, Atmospheric or low pressure plasma deposition (aerosol assisted, . . . ) and/or polymerization, (reactive) Sputtering of metals like Aluminium (Al2O3), Chemical etching (NaOH, . . . ), . . . . Barriers layers may be included.

Metal sheets suitable as substrate for this invention may be typically:
0.5 to 2 mm single sheet metal profile, as made from Al55/Zn45 type coated steel (Aluzinc, Galvalume, Galval, Zincalume), AZ185 with e.g. epoxy coating
0.5 to 2 mm Aluminium sheets (possibly coated to further improve corrosion resistance in aggressive environments)

The metal sheet may be partly corrugated to improve its flexural rigidity. Coatings to improve the adhesion of the metal sheets with polymeric films may be PVC-Vac, PUR, Epoxy, Acrylic, etc. based coatings.

The TPO waterproofing membrane is generally a multi-layer laminated sheet and is reinforced with polyester scrim or fabrics (typically 2*2, 1100 dTex) and/or glass fleece (typically 50 g/m²) and may have a polyester backing to attach the sheet to the insulation panels (with glue or hook and loop systems). More rigid reinforcement (heavy glass scrims, like 3*3, 1360 dTex, etc.) may be preferred to reduce the deformation of the PV cells during heavy storms. The upper layer of the TPO membrane may have a lower melting temperature or higher fluidity than the under layer. The total thickness of the sheet is typically between 0.8 mm and 4 mm, preferably between 1.2 and 3 mm.

Useful TPO compositions to produce the not transparent TPO (thermoplastic polyolefin) layers, including the TPO in contact with the tie-layer, are based on (blends of):
Flexible PP (FPP): PP/EPR reactor blends resins (like Hifax CA 10, Hifax CA 12, Hifax CA 02, Hifax CA 60, . . . supplied by Basell) or elastomers PP resins (like supplied by Dow under the trade name Versify 2300.01 or 2400.01, in mixture with e.g. random PP copolymers) or TPV (Thermoplastic Vulcanisates with little amount of extension oil: Santoprene, etc.)
LLDPE, VLDPE (like Exact 0201 or 8201 supplied by Dexplastomers), OBC (Infuse from Dow) and the like or copolymers (like EVA (ethylene vinyl acetate), EEA (ethylene ethyl acetate), EBA (ethylene butyl acetate), Ionomers, etc.).

The TPO of the tie-layer/TPO will have preferably an higher MFI and/or a lower melting temperature than the (at least lower layer of the) TPO membrane to optimize adhesion. The layers further contain pigments, UV light and thermal stabilizers and flame retardants.

Useful resins to produce tie-layer are:
EAA (Polyethylene Acrylic Acid) polymers
PO (Polyolefins like PE or PP) grafted with maleic anhydride.

Primacor 1321 and Primacor 1410 are examples of EAA resins and are supplied by Dow Chemical. Orevac C314-2 is an example of PP grafted with maleic anhydride (MAH-PP) supplied by Arkema. The resins may be mixed to adapt the Rheology and melting temperature of the tie-layers. To improve transparency and softness of e.g. Primacor 1321 and 1410, copolymers like butyl acrylate, may be added during the polymerization step of such resins. This will anyway reduce the melting temperature. Clarifiers are useful mainly for MAH-PP. They are further stabilized to improve durability.

The tie-layers may also be a coextruded or colaminated A/B/C 3-layer film consisting of:
a TPO inner-layer or core-layer (B layer)
2 thin external tie-layer(s) (A and C layers) consisting of the above mentioned compositions (EAA, EMA, compositions containing Maleic Anhydride grafted polymers)

The external layers (A and C) are preferably thin layers (<150 μm, preferably <50 μm, and typically 5 times thinner than the total thickness of the A/B/C film) and are mainly un-cross-linked but transparent enough, thanks to the small thickness, even if copolymers with high melting temperature (i.e. >95° C.) are used. EAA or EMA resins may be partly neutralized (as well known for the ionomer production) or mixed with ionomers to obtain physical reversible cross-linking.

The TPO inner-layer can be cross-linked, allowing the use of transparent soft co-polyolefins (VLDPE, EVA with >28% VAc, . . . ) with low melting temperature (<85° C.) but low crystallinity (i.e. good transparency). The cross-linking will be performed after the extrusion step (e.g. peroxide cross-linking in a post-curing oven, between release belts; silane cross-linking with humidity, etc. . . . ).

The transparent TPO layer will be typically a mixture of:
30 to 60% by weight random copolymer of polypropylene and ethylene (RCP)
40 to 70% by weight VLDPE (like Exact 8201) to reduce the rigidity of the random copolymer and improve impact resistance
migrating and non migrating Hals and UV absorbers, like Tinuvin 123, Tinuvin 770, Chimassorb 2020 and Benzophenone,
clarifiers (to improve transparency)

Alternatively, the transparent TPO layer may be a mixture of:
60 to 80% ULDPE (like Attane SL 4102—from Dow)
20 to 40% Versify 2400 (Dow).
migrating and non migrating Hals and UV absorbers, like Tinuvin 123, Tinuvin 770, Chimassorb 2020 and Benzophenone,
clarifiers (to improve transparency)

The plastic films and layers will usually be stabilized (with HALS and anti-oxidants, and possibly with UV absorbers) and may contain pigments (opaque layers) and be fire retarded with usual fire retardants. Clarifiers may be used to improve transparency. Anti-acids (acid scavengers, like hydrotalcite and/or metal stearates, etc.) are useful in the core-layers (TPO).

Adhesion promoters (silane, . . . ) may also be added (to improve adhesion with glass fleece, tie-layers, TCO (transparent conductive oxide), etc.). Silane crosslinkers or peroxide crosslinkers may be added to increase the heat distortion temperature of the film, especially of inner-layers like VLDPE, EVA or (F)PP/EVA soft and transparent inner-layers. Other cross-linking techniques (gamma, X-ray, EBC, UV light, sun-light . . . ) and adapted cross-linkers and initiators (like photo-initiators) may also be used.

Care has to be taken not to neutralize the reactive comonomers (acrylic acids) or grafted monomers (Maleic Anhydride) of the tie-layers by addition of reactive additives during the extrusion step. It is preferred to add these additives in the core-layer. Low molecular weight additives are useful as they may migrate to the tie-layers during the lamination step (i.e. when the acid-base adhesion reaction of the tie-layer on e.g. Al2O3 is already obtained).

To decrease module temperature in use, the modules with a metal sheet as under layer may be installed with the help of profiles. To this end, profiles are attached to the roof by one of welding, gluing or mechanical fixing (like nails, screws or hook and loop), etc. The modules are attached on the profiles, with air circulation under the modules. This allows with high safety margin the use of tie-layer on base of EAA like Primacor 1321 or even 1410, as will be recognized by the man skilled in the art on base of the following data's:

| Primacor | 1321 | 1410 |
|---|---|---|
| Tm (DSC ° C.) | 101 | 96 |
| Vicat (° C.) | 90 | 81 |
| Comonomer (%) | 6.5 | 9.7 |

EP 0769 818 A2 indicates the difficulty to obtain PV modules with a thick layer of plastic film (>800 μm) above the metal sheet.

To obtain a low flammability photovoltaic TPO waterproofing membrane (or flexible module) containing “plastic cells”, it is preferred to eliminate the glass fleeces in the transparent adhesive layer (contrary to the teaching of EP 0769 818 A2) while further providing a back layer (i.e. under the plastic cell) containing sheets or films which are flame retarded by halogenated, preferably brominated flame retardants and the sheets or films should have a low tendency to charring or forming fire barrier materials. It is indeed necessary that the flame retardant decomposition products can be released and reach the flame to poison it. Therefore, these sheets or films and the sheets or films above these sheets or films are selected on the base that they have no or little tendency to char or to form a barrier layer for the release of the flame retardants decomposition products into the flame. Therefore, no glass fleeces should be included or at least are required into the transparent adhesive layer and the layers under the cells should contain layers based on TPO resins and/or Polyethylene with adequate comonomers (Vinyl acetate, acrylates, neutralized acrylic acids, . . . ), containing preferably brominated flame retardants, materials which are known for their low charring tendency. It has been discovered that even a 1 mm thick (>0.8 mm) EVA transparent adhesive may be used for the front sheet, if enough preferably brominated flame retardant is added to the back layer. Sufficient inflammability is achieved with improved mechanical properties (thicker protective EVA transparent adhesive).

The adhesive (EVA, “tie-layer/TPO”, . . . ) of the back layer (i.e. layer d) may be formulated with halogenated compounds and catalyst (Sb2O3) and will contain at least 50 g/m², preferably at least 100 g/m², of the halogenated, preferably Brominated flame retardant, in order to be able to release enough (Halogene/Bromine) radicals into the flame (to “poison” the flame propagation) when the module catches fire. It has been surprisingly discovered that, when a plastic cell substrate (cell on plastic) is used, a low flammability can nonetheless be obtained by incorporation of such adhesive layer, even if the sheets/foils/films under the adhesive (EVA, . . . ) layer are charring type materials like P-PVC or TPO with charring flame retardants. Preferably and contrary to the teaching of EP 0769 818 A2, there is no glass fleece in the EVA transparent adhesive layers above the cell. The glass fleece would limit the access of the Halogene radicals to the flame.

The halogenated flame retardants are preferably brominated flame retardants, preferably in combination with catalysts like Sb2O3 or Sb2O5. Other flame retardants may be added like Zink Borates, etc.

According to this invention, the TPO waterproofing membrane may contain Halogen flame retardant in its full thickness. As the TPO membrane is generally not fully covered by the PV cells and their encapsulation layers, a.o. e.g. ETFE (in order to allow for e.g. weldability of the membrane and or replacement of a damaged PV module), the addition of halogenated flame retardants in the upper layer of the TPO membrane will lead, due to the TPO photooxidation, to release of halogenated compounds into the environment. Halogenated flame retardants are further expensive, especially when UV stability is required. Even with the more stable halogen flame retardants, a decrease of the UV stability is expected.

It has been surprisingly discovered that satisfactory fire performances of the membrane (areas with and without PV cells and encapsulation layers) can be achieved with an upper layer of the TPO membrane not containing halogenated flame retardants: the flame retardant decomposition products can be released and reach the flame to poison it, even at the level of the plastic PV cell(s). The UV aging of such TPO membrane is therefore not impaired by the halogen flame retardants and its price is reduced.

Further the invention provides a tie-layer/TPO composition (layer d) to improve the fire performances of PV TPO waterproofing membrane with plastic cells, where the TPO waterproofing membrane contains classical mineral flame retardants like Mg(OH)2 or Al(OH)3 charring flame retardants. Such “tie-layer/TPO” layer d) is formulated with halogenated compounds and catalyst (Sb2O3) and will contain at least 50 g/m², preferably at least 100 g/m², of the halogenated, preferably Brominated flame retardant.

It has surprisingly been discovered that while known plastic PV cells and their encapsulants lead to a loss of fire performances of conventional TPO membrane (halogen free flame retardants), the above mentioned tie-layer/TPO composition compensates the loss of fire performances, which is the result of the plastic PV cell(s) with transparent encapsulants.

Such tie-layer/TPO composition will allow to increase the thickness of EVA layer b), when superior mechanical properties are required and that the PV TPO waterproofing membrane may be installed on more critical roof structure (roof structure with lower fire performances).

It has also been surprisingly discovered that excellent external fire properties may be obtained when plastic PV cells are laminated on thick metal sheets: such sheets act as heat sink and therefore significantly limit fire propagation.

The invention will be illustrated further by reference to the attached drawings which are not meant to restrict the scope to the specific embodiments shown. Other combinations of the preferred features than those shown are also possible and advantageous. The drawings are showing:

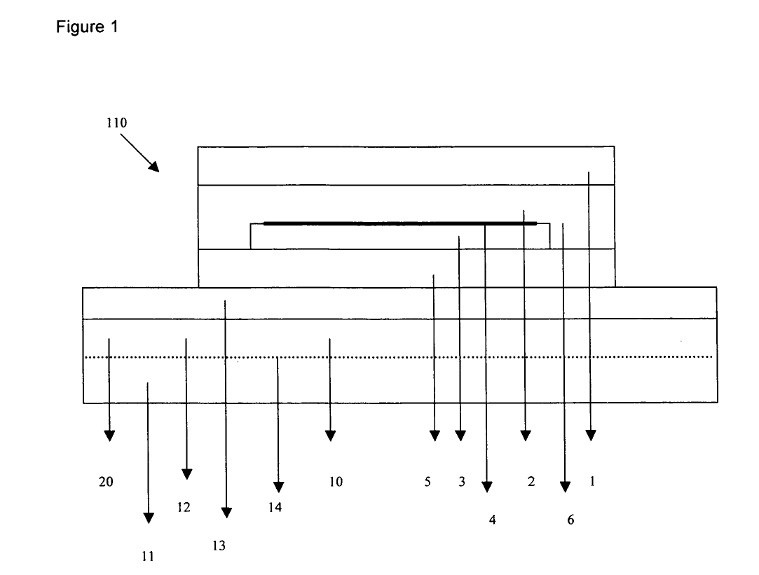

FIG. 1 a cross section of a PV module (110) according to this invention, e.g. a PV integrated waterproofing membrane or a PV metal sheet

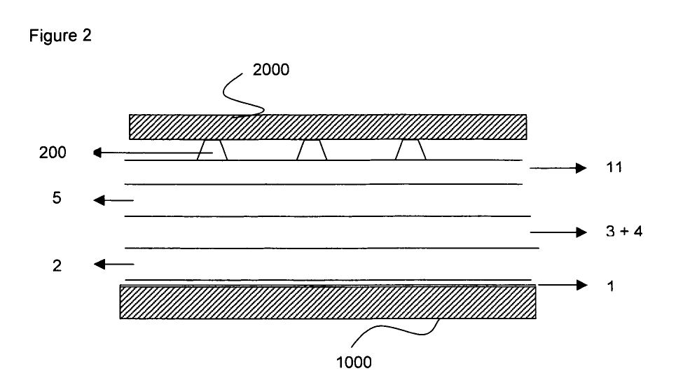

FIG. 2 a cross section through an integrated PV module according to this invention, produced in a one step process.

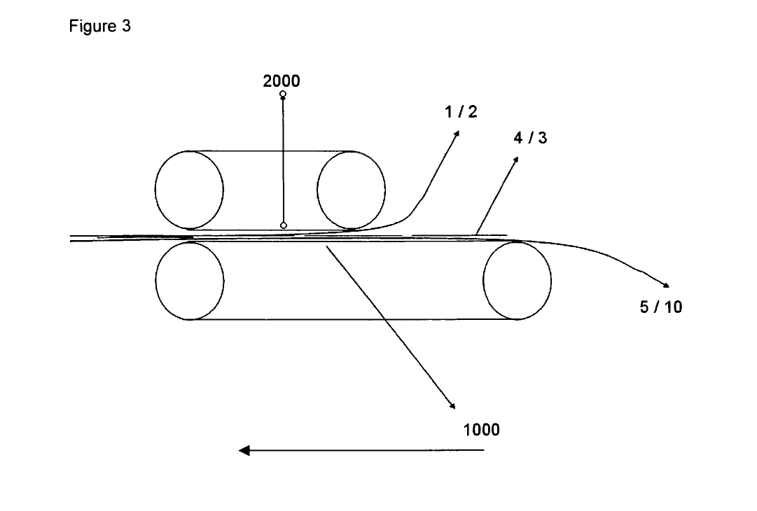

FIG. 3 a schematic representation of a double-belt press production of a PV waterproofing membrane

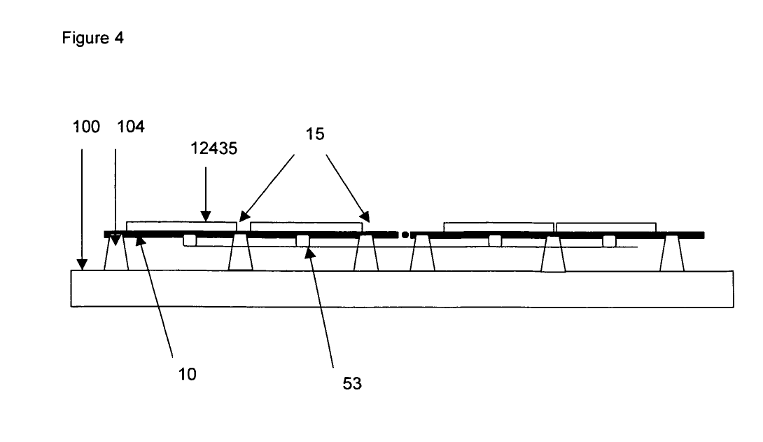

FIG. 4 a schematic view of a roof integration of a module of this invention.

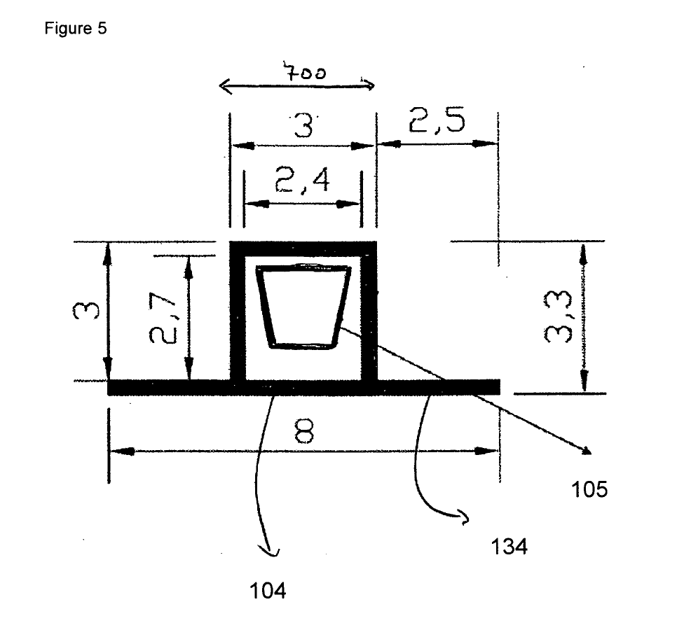

FIG. 5 a detail view of a profile used to attach module of FIG. 4 to a roof structure.

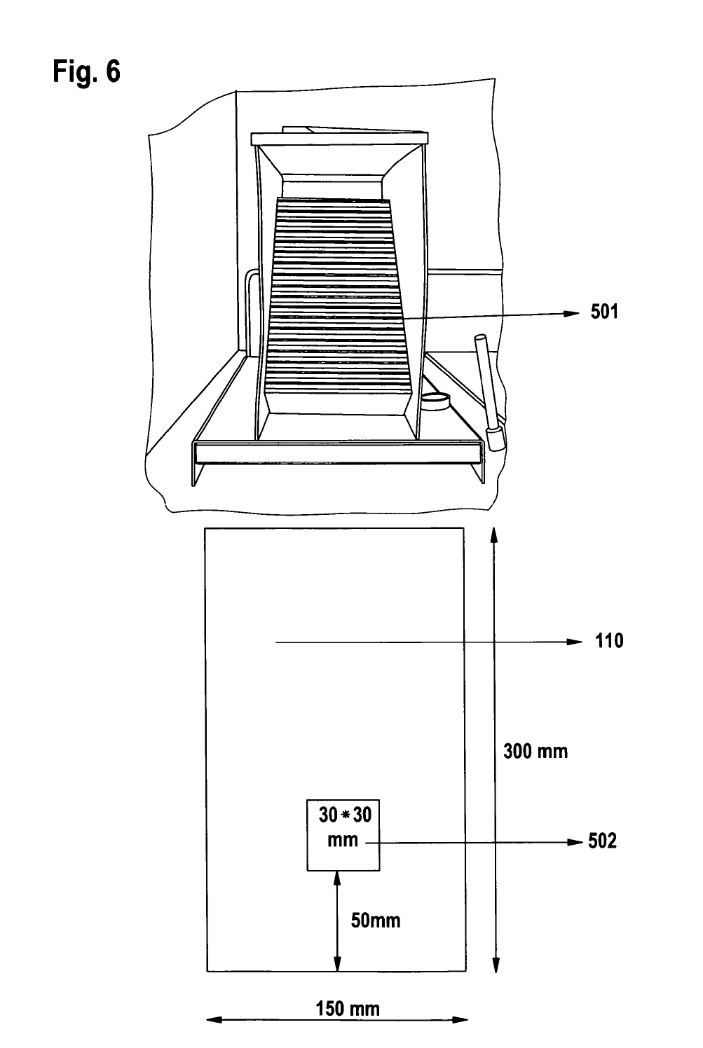

FIG. 6: shows a view of a laboratory fire test set up

In the variant of a waterproofing PV membrane the layers shown in FIG. 1 are as follows: a multilayer TPO waterproofing membrane (10), typically 1.5 mm thick with a underlayer (11), an intermediate layer (12) and upper layer (13) and a reinforcement (14), typically a polyester scrim or a glass scrim or a polyester/glass fleece combi-mat. The upper layer (13) is typically 0.25 mm thick. The TPO membrane (10) may be wider that the PV module: a zone (20) is foreseen for welding purpose (installation, repair, . . . ). The TPO membrane contains further heat and UV stabilizers which may migrate into layer (5) to avoid any risk of depletion of stabilizers in the layers (5) and (2) (edges 6).

On top of the TPO waterproofing membrane, one laminates, e.g. in a classical vacuum laminator or in a membrane press (e.g. WEMHÖNER VARIOPRESS®—press size 1.7*6 m²) or in e.g. a double-belt press (semi-continuous process) the following stack of layers:
a) A transparent front sheet (1)
b) A transparent adhesive layer (2)
c) The plastic (3) PV cells (4)
d) An adhesive layer (5) which is preferably opaque and of light color (high solar reflectance)

The layer a), b) and d) are wider than c), allowing for edge sealing (6) of the plastic PV cell (PET, PEN, . . . film) (4), reducing significantly the risk of internal delamination and allowing improved long term safety compared to the previous art where the dielectric PET film is included into the edges of the modules (Uni-Solar modules).

Further the color of the TPO waterproofing membrane may be white or light grey, limiting the temperature at the edges (6) of the plastic PV cells and the risk of excessive temperature and start of fusion of the e.g. tie-layer/TPO adhesive layer.

In the case of a PV integrated metal sheet the layers in FIG. 1 are as follows: a metal sheet (10), typically 1.5 mm thick with a metallic substrate (11), typically 1 mm aluminium, a glue layer, e.g. a tie-layer (12) and a e.g. TPO upper layer (13). The upper layer (13) is typically 0.5 mm thick to achieve enough dielectric strength (1 kVolt partial discharge requirements). The TPO metal sheet (10) may be wider that the PV module (1 to 5): a zone (20) is foreseen on each sides for e.g. corrugation or for folding the metal sheet (to obtain 2 rigidifying ribs) and/or for mechanical fasteners or for welding purpose (connection with TPO installation strips, . . . ). The TPO upper layer (13) contains further heat and UV stabilizers which may migrate into layer (5) to avoid any risk of depletion of stabilizers in the layers (2) and (5) (edges 6). The same stabilizers will migrate into layer (12), being the tie-layer for the metal substrate (11).

On top of the metal sheet (10), including layers (11), (12) and (13), one laminates, e.g. in a classical vacuum laminator or in a membrane press (e.g. a WEMHÖNER VARIOPRESS®—press size 1.7*6 m²) or in e.g. a double-belt press (semi-continuous process) the following stack of layers:
a) A transparent front sheet (1)
b) A transparent adhesive layer (2)
c) The plastic (3) PV cells (4)
d) An adhesive layer (5) which is preferably opaque and of light color (high solar reflectance)

The layer a), b) and d) are wider than c), allowing for edge sealing (6) of the plastic PV cell (PET, PEN, . . . film) (4), reducing significantly the risk of internal delamination and allowing improved long term safety compared to the previous art where the dielectric PET film is included into the edges of the modules (Uni-Solar modules).

Further the color of the metal sheet (10) may be white or light grey, limiting the temperature at the edges (6) of the plastic PV cells and the risk of excessive temperature and start of fusion of the e.g. tie-layer/TPO adhesive layer.

Alternatively layer (5)/(13)/(12) may be one coextruded or colaminated layer, i.e. a tie-layer/TPO/tie-layer which is used to glue the aluminium substrate (11) to the plastic (3) PV cells substrate.

FIG. 2 shows a stack of layers (1/2/3+4/5) of a PV module (110) laminated in a one step process in a membrane press on a metal substrate (11) with a corrugated backing or profiles (200) to improve flexural modulus of the PV module. 1000 is the heating support of the press and 2000 is the flexible pressing membrane, following the corrugation. The module has an adhesive layer 5 (e.g. tie-layer/TPO/tie-layer), a, e.g. plastic film with electrodes and active layers (3+4), a transparent plastic adhesive layer (2), possibly with high barrier properties and a fluoropolymer top film (1).

FIG. 3 shows a schematic representation of a double-belt press production of a Integrated PV module (110) of this invention. On the preparation table part of the double-belt press (1000), one unwinds a roll or a coil of a complex (5/10) which can be:
a polyester/glass-fleece TPO waterproofing membrane (10) which is already laminated with a tie-layer (5), e.g. during and by extrusion coating of the tie-layer (5) on the waterproofing membrane (10):
   i) (5)=a 50 μm film of Orevac C314-2 with usual additives and if required flame retardants
   ii) (10)=a TPO waterproofing membrane (on base of Hifax CA 10 A, polyester and glass-fleece reinforced, containing usual additives and flame retardants).
a metal sheet (10) like a aluminium sheet already laminated with a tie-layer/TPO/tie-layer (5), e.g. during and by extrusion coating of the tie-layer/TPO/tie-layer (5) on the metal sheet (10).

The plastic film PV cells (4/3) are fed discontinuously in the double-belt laminator, i.e. in the form of long rectangles (typically 6 m long; if required several rectangles in parallel). For this purpose, they are laid by robots (handling by e.g. sucking devices) in parallel, serial connected (not shown), on the complex (10/5), on the preparation zone of the double-belt press, The plastic film PV cells is held in good contact with the complex (10/5) e.g. electrostatically (metal belt). Typically 10 cm without cell are foreseen in the length between the parallel formats of plastic PV cells to allow cutting and edge sealing.

The plastic PV cells (4/3) are further laminated with a film (1/2) which is a complex of:
typically an ETFE (1), surface treated to show good adhesion with (2)
a tie-layer/transparent TPO/tie-layer (2), which is laminated on (1) during and by extrusion coating of the tie-layer/transparent TPO/tie-layer (2) on (1)
   The final laminate is cut into formats. Electrical connections (perforation—contacts—soldering) are done off-line.

FIG. 4 shows a schematic view of a roof integration of a rigid module (110) of this invention: On the waterproofing membrane (100) already installed on a roof structure, one welds soft profiles (104). On these profiles (104), one fastens the rigid module (110) being e.g. a metal sheet (10) with layers (1/2/4/3/5); typical size=6*1 m². Zones without cells (15) are used to attach the modules with e.g. self-drilling screws on the profiles (104). Connections between modules (110) can be done under the modules (53).

FIG. 5 shows a detail of a profile used to attach a module of FIG. 4: The soft profile (104) has flaps (134) for welding the profiles onto the waterproofing membrane. The modules are attached to the profiles (104) by screws perforating the soft profile and fastened into the metal insert (105) inside the soft profile (104). The profile (104) is soft and can follow the expansion-contraction movements of the modules (700). Ventilation and cooling under the modules (110) will limit the temperature of the modules.

FIG. 6 shows a view of a laboratory fire test set up used for this invention and useful for comparison purpose: The test equipment comprises a ZIP firelighter being a pressed block of rough pinewood sawdust and paraffin wax (30*30*17 mm), a test box with supporting deck made from metal, and for a draught free test enclosure an exhaust hood to evacuate the smoke production, avoiding draught over the specimen. The test specimen is the waterproofing membrane, with (110) or without plastic cells (10), installed on 5 cm thick rockwool (501) as isolation material, with the following dimension: 150 mm in width×300 mm in length. The test procedure is as follows:

Positioning of the brand 502 (ZIP firelighter) before ignition at a distance of 50 mm from the lower edge of the specimen and centrally between the left and right edge

Test angle=45°

The brand (ZIP firelighter) is ignited

duration of the test is 20 minutes

observation and measurement of the burnt surface.

### EMBODIMENTS

### Embodiment 1

### Modules with Metal Substrate—Demonstration of Quality of Adhesion, Durability, Electrical Safety and Fire Safety

Module M3 is produced by well known lamination methods, e.g. according to EP 0769818 A2 and comprises the following stack of layers:
a) An ETFE film 50 μm from DuPont (with surface treatment to adhere to EVA)
b) A stack of two EVA Vistasolar 486.10 films (thickness+/−460 μm)
c) A 50 μm PEN film, supporting the active layers (e.g. TCO/pin/back electrode/adhesion layer/adhesive to PEN) with an Al2O3 coating (reactive sputtering) at the back side of the PEN film
d) A coextruded film of “50μ EAA Primacor 1410/900 μm VLDPE Exact 0203/50 μm EAA Primacor 1410”, containing (mean values, not added in all layers to avoid neutralization of acrylic acid functionalities) anti-oxidants (0.3% Irganox B225 from Ciba), HALS (0.3% Tinuvin 770 and 0.3% Chimassorb 944), acid-scavengers, pigments (5% TiO₂ Kronos 2220), 24% Saytex 8010 and 8% of Sb₂O₃.
e) A 1 mm Aluminium plate, if required coated as known per se to further improve corrosion/chemical resistance.

Layers a), b), d) and e) are 4 cm wider and longer than layer c) to obtain 2 cm sealed sides. Small modules are produced for water immersion and fire assessment.

After 4 weeks of immersion into water 80° C., there is no delamination of the primacor 1410 from the EVA. The electrical safety of the module is kept. By comparison, a Uni-solar module shows clear delamination between the PET film and the EVA layers. Further, no corrosion is observed!

To evaluate (comparative tests) fire performance, modules according to this invention, without the photoelectric layers, are placed in a frame (30*30 cm²) at an angle of 45° against the horizon and submitted during 2 minutes to a gas burner flame (760° C. +/−40° C.). The upper side of the modules (i.e. the side normally exposed to the sun) is looking to the flame. The time until the modules are extinguished (self-extinguishing time) and the damaged surface area are observed. The following module constructions have been assessed (variations of embodiment 1.1) versus a well-known construction (M4), equivalent to the Kalzip® AluPlusSolar product approved for pitched roofs with slopes up to 60°. The results are summarized in the following table:

| | | | | Module M4 |
|---|---|---|---|---|
| layer | Module M1 | Module M2 | Module M3 | (≡AluPlusSolar) |
| a) | 50 μm ETFE | 50 μm ETFE | 50 μm ETFE | Uni-Solar PVL |
| b) | 660 μm EVA | 920 μm EVA | 920 μm EVA | 136 (*) |
| c) | 50 μm PEN - | 50 μm PEN - | 50 μm PEN - | |
| | cells | cells | cells | |
| d) | 200 μm EVA | 460 μm EVA | 1000 μm tie/ | |
| | | | TPO/tie (**) | |
| e) | 1 mm alu | 1 mm alu | 1 mm alu | 1 mm alu |
| | plate | plate | plate | plate |
| Self-estin- | 2 minutes | 7 minutes | 2 minutes | 11 minutes |
| guished | | | | |
| Damaged | 8.000 mm² | 16.000 mm² | 3.500 mm² | 7.000 mm² |
| surface | | | | |

(*) Peel and Stick module consisting of 50 μm ETFE/500 μm transparent EVA with glass innerlayers/120 μm stainlesss steal foil with active layers/back sheet (EVA/PET/EVA)/EPR adhesive.
(**) Module M3 according to this invention.

The module M3 according to this invention is produced in one step process on aluminium panel with thick encapsulating layers (electrical safety and durability). Excellent fire performances are possible and even better than for the previous art (metal foil as substrate for the PV cells).

The module M1 behaves at the same level or better as the reference module M4 (used today with success for metal roofs with slope up to 60°). This is surprising as the thickness of the EVA/PEN/EVA organic films above the metal sheet is more than 800 μm. This shows the heat sink and thermal conductivity effect of the thick metal plate (>0.5 mm). The module M3 behaves even better than the reference module M4, although the thickness of EVA above the cell is more than 800 μm.

### Embodiment 2

### Demonstration of Fire Safety of TPO Waterproofing Membrane (10) with Plastic PV Cells (110)

### Example 1

Sample A is a polyester reinforced 1.5 mm multi-layer TPO waterproofing membrane (10) according to this invention with halogenated flame retardants. The composition of the multi-layer membrane is:
300 μm top layer of Hifax CA 10 A with usual stabilizers and pigments and with 25% Saytex BT 93 halogenated flame retardant and 10% Sb2O3.
600 μm intermediate layer of Hifax CA 10 A with usual stabilizers and pigments and with 17% Saytex 8010 halogenated flame retardant and 6% Sb2O3
2*2 1100 dTEx Polyester reinforcement.
600 μm lower layer of Hifax CA 10 A with usual stabilizers and pigments and with 17% Saytex 8010 halogenated flame retardant and 6% Sb2O3

The burnt surface after fire testing is 3200 mm².

Sample B is the same TPO waterproofing membrane (10) with laminated on top of it the following stack of layers:
a) 50 μm ETFE with surface treatment to adhere to b)
b) 460 μm Etimex Vistasolar 486.10
c) a simulated Plastic PV cell (a PET film with an aluminium top coat obtained by PVD; back side treated by atmospheric plasma, as well known by the man skilled in the art)
d) 460 μm Etimex Vistasolar 486.10 which simulates a Tie-Layer/TPO:
   a. Tie-layer=100 μm Orevac C314-2 (MAH grafted PP),
   b. TPO=360 μm of Hifax CA 60 with usual stabilizers and pigments.

The burnt surface after fire testing is 1700 mm². Surprisingly the stack of layers a) to d) doesn't reduce the fire performances of the obtained PV waterproofing membrane (110) of this invention. It is even reduced, although the total thickness of non flame retarded film b), c) and d) is 970 μm.

### Comparison Example 2

Sample C is a conventional polyester reinforced TPO waterproofing membrane (10) on base of Hifax CA 10 A with usual additives and pigments, containing a high loading (45%) of Mg(OH)2 fire retardants. This waterproofing membrane needs a polyester reinforcement to compensate for the severe reduction in mechanical properties. The burnt surface after fire testing is 2500 mm². The burnt part of the sample shows a mineral crust (char). Sample C shows better fire performance than sample A).

Sample D is the same TPO waterproofing membrane as C but with laminated on top of it the following stack of layers:
a) 50 μm ETFE with surface treatment to adhere to b)
b) 460 μm Etimex Vistasolar 486.10
c) a simulated Plastic PV cell (a PET film with an aluminium top coat obtained by PVD; back side treated by atmospheric plasma, as well known by the man skilled in the art)
d) 460 μm Etimex Vistasolar 486.10 which simulates a Tie-Layer/TPO:
   a. Tie-layer=100 μm Orevac C314-2 (MAH grafted PP),
   b. TPO=360 μm of Hifax CA 60 with usual stabilizers and pigments.

The burnt surface after fire testing is 5000 mm². As should be expected on base of the teaching of EP 0 769 818 A2, the stack of layers a) to d) (the total thickness of non flame retarded film b), c) and d) is 970 μm.) reduces significantly the fire performances of the obtained PV waterproofing membrane (110).

### Example 3)

Sample E is the same TPO waterproofing membrane as C but with laminated on top of it the following stack of layers:
a) 50 μm ETFE with surface treatment to adhere to b)
b) 460 μm Etimex Vistasolar 486.10
c) a simulated Plastic PV cell (a PET film with an aluminium top coat obtained by PVD; back side treated by N2/NH3 atmospheric plasma, as well known by the man skilled in the art, for adhesion to Orevac C314-2)
d) a Tie-Layer/TPO:
   a. Tie-layer=100 μm Orevac C314-2 (MAH grafted PP),
   b. TPO=500 μm of Hifax CA 60 with usual stabilizers and pigments and containing 25% of Saytex 8010 and 8% of Sb2O3. The amount of halogenated flame retardant is around 125 g/m².

The burnt surface after fire testing is 1600 mm². Surprisingly the obtained PV waterproofing membrane (110) of this invention shows excellent fire performances.

### Example 4

### Top Layer (13) without Flame Retardant

The following multi-layer membrane is submitted to the laboratory fire test:
300 μm top layer of Hifax CA 10 A with usual stabilizers and pigments and without fire retardants.
600 μm intermediate layer of Hifax CA 10 A with usual stabilizers and pigments and with 22% Saytex 8010 halogenated flame retardant and 7% Sb2O3
2*2 1100 dTEx Polyester reinforcement.
600 μm lower layer of Hifax CA 10 A with usual stabilizers and pigments and with 22% Saytex 8010 halogenated flame retardant and 7% Sb2O3

The burnt surface after fire testing is surprisingly limited to 3300 mm².

After lamination with the same layers a) to d) of sample B, the obtained PV TPO waterproofing membrane (or module) 110, is tested in the laboratory fire test. The burnt surface after fire testing is surprisingly limited to 1800 mm².

### Embodiment 3

### Production of PV TPO Waterproofing Membrane (110) with Sealed Edges, Good Hot Water Resistance and Fire Properties

A photovoltaic cell is produced according WO 98/13882 and glued onto a plastic film (PEN or PET), cell substrate. This PEN or PET film, with the active photovoltaic layers is encapsulated in a vacuum laminator according to a procedure well known to persons normally skilled in the art (release films may be used between the TPO membrane—layer e)—and the heating plate system) and comprises the following layers:

a) An ETFE film 50 μm from DuPont (supplied for PV applications; with classical atmospheric plasma treatment to adhere to EVA)
b) Two EVA Vistasolar 486.10 films of +/−460 μm
c) Several 50 μm aligned in parallel PEN films supporting the active layers (stripes of interconnected TCO/pin/back electrode) and interconnected. The back side of the PEN film is e.g. treated by reactive sputtering (deposition of a nano-layer of Al2O3) to improve adhesion with the Primacor (EAA) film.
d) A coextruded multi-layer of:
i) 50 μm Primacor 1410 or 1321
ii) 50 μm Exact 0203
iii) 50 μm Exact 0203/Hifax CA 60/Versify 2400.00 in mixture each layer containing anti-oxidants (e.g. 0.3% Irganox B225 form Ciba), HALS and UV absorbers (e.g. 0.3% Tinuvin 770, e.g. 0.3% Chimassorb 944 and e.g. 0.3% Chimassorb 81), pigments (e.g. 5% TiO2 Kronos 2220), halogenated flame retardants (e.g. 30% Saytex 8010) and e.g. 8% of Sb2O3 as catalyst. The EAA Primacor layer shows excellent adhesion to PEN films (with deposition of a nano-layer of Al2O3). The HALS are preferably not added to the Primacor 1410 or 1321 layer at the extrusion step (compounding stage) but are added to the layers ii) and iii) and migrate from these layers to layer i) during the lamination process and during aging. Tinuvin 123 may be preferred above Tinuvin 770. Other NOR-HALS (less reactive with acids groups) may be used as defined by the man skilled in the art. Anti-acids are only added to layer ii) and iii).
   e) A 1.2 mm TPO sheet on base of Hifax CA 10 A with usual stabilizers, including acid-scavengers and pigments and brominated flame retardants, like 25% Saytex 8010 and 7% Sb2O3. The TPO sheet may contain a reserve of e.g. HALS stabilizers of UV absorbers, which will migrate into layers a), b) and d). The top layer of the TPO sheet may contain softening resins like Exact 0201, Hifax CA 60 and/or Versify 2400.00 to optimize adhesion with layer d), part iii).

The layers a), b), d) are longer and wider (2 cm on each sides) than the layer c) to seal the edges of the cells efficiently (lower risk of delamination). A velour (a Loop fleece) or a hook may be laminated or glued at the back side of the photovoltaic TPO waterproofing membrane (application as flexible module).

To illustrate the fire performances, several hereabove described flexible module (although “inactive”, i.e. with layer c) without the active layers) are attached side by side (flaps 20 covered by aluminum strips or welded together) on an existing 1.2 mm Alkorplan 35176 waterproofing sheet (substrate=insulation panels: 6 cm commonly used mineral wool). The Alkorplan 35176 waterproofing membrane is equipped with 10 cm width hooks strips (e.g. mushrooms strips stitched on strips of the same P-PVC membrane). 3 strips/meter are welded in parallel on the Alkorplan 35176 membrane. The structure is tested and passes with success the external fire performance tests ENV 1187/1 15°, thanks to the halogenated flame retardants which are released to the flame and poison it.

It has to be recognized that the flexible modules (the photovoltaic TPO membrane) may be installed in big panels with sealed perimeter and connected to venting profiles to limit water accumulation under the modules.

The flexible modules may be installed as mono-layer (as photovoltaic integrated waterproofing membrane; preferably on a roof substrate including an efficient water vapor barrier) or welded on an existing TPO membrane (double-layer system).

A piece of a Uni-Solar module PVL-series, model PVL 128 has been aged during 3 months in water at 60° C. and tested for delamination. The Uni-Solar module shows delamination at the level of the inferior PET film (PUR adhesive hydrolysed). In the same test, the module according to this invention, with sealed edges (2 cm), doesn't suffer from delamination, as the adhesion between layer b) and d) is excellent (not sensitive to hydrolysis).

### Embodiment 4

### Production of a TPO Photovoltaic Waterproofing Membrane (or Flexible Module) in One Step in a Semi-Continuous Process

In a double-belt (1000-2000) press (with Teflon® release treatment of the belts) one laminates (press temperature around 175° C.) the following layers:

I) A layer (1/2) obtained by extrusion coating of layer b) on a):
a) a (1) 100 μm ETFE film preferably with UV absorbers, plasma treated (atmospheric plasma treated—N2/NH3 atmosphere) to adhere with
b) a (2) coextruded film (brushed surface) of:
   i) 25 μm of Orevac C314-2 with usual stabilisers (not reacting during the extrusion step with the MAH functionalities and allowing transparency)
   ii) 300 μm of a transparent TPO composition like e.g.:
      a mixture of random polypropylene-ethylene copolymer and VLDPE like Exact 8201 (60/40 ratio), containing migrating and non migrating Hals and UV absorbers, like Tinuvin 123, Tinuvin 770, Chimassorb 2020 and Benzophenone, with clarifiers to improve transparency and transparent anti-acid
   iii) 25 μm of Orevac C314-2 with usual stabilisers (not reacting during the extrusion step with the MAH functionalities and allowing transparency)
      II) plastic PV cells formats (4/3):
c) formats of plastic PV cells (if required with barrier layers and with surface treatment like e.g. a sputtered nanometric layer of Al2O3on both sides for reaction with the MAH functionalities of the Orecac C314-2 layers), interconnected in parallel
   III) A complex (5/10):
d) a complex produced by in-line co-extrusion—laminating of:
   iii) (5) a 50 μm film of Orevac C314-2 with usual additives and if required flame retardants
   iv) (10) a TPO waterproofing membrane (on base of Hifax CA 10 A, polyester and glass-fleece reinforced).

The plastic PV cells (4/3) are fed discontinuously in the double-belt laminator, i.e. in the form of long rectangles (typically 6 m long; if required several elements in parallel). For this purpose, they are laid in parallel on the preparation zone of the double-belt press on the complex d), serial connected. Typically 10 cm without cell are foreseen in the length between the parallel formats of plastic PV cells to allow cutting and edge sealing. The layers a) and b) are preferably already laminated during an adequate production process, e.g. by extrusion coating of layer b) on layer a). The films a/b) and d) are fed continuously into the double-belt press. They are wider than the plastic cells to seal the edges. Layer d) is of light color (high solar reflectance). The final laminate is cut into formats. Electrical connections (perforation—contacts—soldering) are done off-line.

As will be apparent the foregoing description does not cover all possible combinations. Other combinations may be derived by the man skilled in the art from the present description and are useful.

1-16. (canceled)

17. Integrated Photovoltaic Modules laminated in a one step process comprising:
a substrate
a thermoplastic adhesive layer
at least two interconnected cells and
a superstrate
wherein the substrate comprises a thermoplastic polyolefin membrane or layer and the adhesive is a co extruded tie layer/thermoplastic polyolefin comprising a tie layer on base of polyolefin copolymers and a thermoplastic polyolefin layer wherein the thermoplastic polyolefin of the tie-layer/thermoplastic polyolefin has a higher MFI and/or a lower melting temperature than the at least lower layer of the thermoplastic polyolefin membrane of the substrate and wherein the thermoplastic polyolefin of the adhesive is chosen from Flexible PP or blends thereof with LLDPE, VLDPE, OBC and the like and wherein the thermoplastic polyolefin membrane or layer of the substrate is based on Flexible PP, like PP/EPR reactor blends resins or elastomers PP resins, Thermoplastic Vulcanisates with little amount of extension oil, or blends thereof.

18. Integrated Photovoltaic Modules of claim 17, wherein the interconnected cells are built on a film.

19. Integrated Photovoltaic Modules of claim 18, wherein the interconnected cells are protected by a superstrate consisting of a transparent adhesive layer (2) and a flexible fluoropolymer front sheet.

20. Integrated Photovoltaic Modules of claim 17, wherein the adhesive layer and substrate are a coextruded or extrusion laminated complex (5/10).

21. Integrated Photovoltaic Modules of claim 20 containing under the cells substrate at least 50 g/m², preferably at least 100 g/m² of halogenated flame retardant, preferably brominated flame retardant.

22. Integrated Photovoltaic Modules of claim 21, wherein the adhesive layer is a tie-layer thermoplastic polyolefin containing at least 50 g/m², preferably at least 100 g/m² of halogenated flame retardant, preferably brominated flame retardant.

23. Integrated Photovoltaic module according to claim 17, wherein the adhesive layer above the plastic PV cells is a transparent tie-layer/thermoplastic polyolefin/tie-layer adhesive.

24. Integrated photovoltaic module according to claim 17 produced in a double-belt press.

25. Integrated photovoltaic module according to claim 17, with sealed edges.

26. Integrated photovoltaic module according to claim 17, wherein a thermoplastic polyolefin core layer contains acid scavengers.

27. Integrated photovoltaic module according to claim 17, wherein at least one tie-layer contains HALS and/or UV absorbers and/or acid-scavengers through migration from adjacent layers during lamination and on site.

28. Integrated photovoltaic module according to claim 17, wherein the waterproofing membrane contains migrating UV absorbers and migrating HALS to improve stability of the edges.

29. Integrated Photovoltaic modules according to claim 17, wherein the substrate is a glass reinforced plastic sheet, wherein the interconnected cells are built on a film and protected by a superstrate consisting of a transparent adhesive layer and a flexible front sheet.

30. Integrated Photovoltaic modules according to claim 29, wherein the adhesive layer is a tie-layer/thermoplastic polyolefin containing at least 50 g/m², preferably at least 100 g/m² of halogenated flame retardant, preferably brominated flame retardant.

31. Integrated Photovoltaic Modules of claim 18, wherein the adhesive layer and substrate are a coextruded or extrusion laminated complex (5/10).

32. Integrated Photovoltaic module according to claim 18, wherein the adhesive layer above the plastic PV cells is a transparent tie-layer/thermoplastic polyolefin/tie-layer adhesive.

33. Integrated Photovoltaic module according to claim 19, wherein the adhesive layer above the plastic PV cells is a transparent tie-layer/thermoplastic polyolefin/tie-layer adhesive.

34. Integrated photovoltaic module according to claim 18, wherein a thermoplastic polyolefin core layer contains acid scavengers.
